(19) United States
(12) Patent Application Publication
(10) Pub. No.: US 2025/0343532 A1
(43) Pub. Date: Nov. 6, 2025

(54) METHOD AND DEVICE FOR CONTROLLING AN OUTPUT RESISTANCE OF A DATA TRANSMITTER

(71) Applicant: STMicroelectronics International N.V., Geneva (CH)

(72) Inventors: Isabelle CLAVERIE-BELLIARD, GREASQUE (FR); Francois COURBIN, Roquevaire (FR)

(21) Appl. No.: 19/185,583

(22) Filed: Apr. 22, 2025

(30) Foreign Application Priority Data
May 6, 2024 (FR) FR2404719

(51) Int. Cl. H03K 3/011; H03K 17/687

(52) U.S. Cl. CPC H03K 3/011; H03K 17/6871

(57) ABSTRACT

The present description concerns a data transmission circuit comprising an output branch comprising a first resistor, a first transistor, and a second transistor series-connected between a first voltage rail and a first output node, the second transistor being configured to receive on its gate a data signal; a branch of duplication of the output branch, between the first voltage rail and a second node; a current source coupling the second node and a second voltage rail; and a voltage control circuit configured to control a gate voltage.

### CROSS REFERENCE TO RELATED APPLICATIONS

This application claims the priority benefit of French patent application number FR2404719, filed on May 6, 2024, entitled “Procédé et dispositif de contrôle d'une résistance de sortie d'un transmetteur de données”, which is hereby incorporated by reference to the maximum extent allowable by law.

### TECHNICAL FIELD

The present disclosure generally concerns electronic circuits and more particularly a data transmission circuit and method.

### BACKGROUND

A data transmission circuit is associated with an output resistance. In some cases, it is desirable to maintain an output resistance within a range of values to limit losses during data transmission, or when a standard constrains the output resistance within a range of values.

There exist solutions to adjust the output resistances of a data transmission circuit. However, existing solutions do not sufficiently accurately compensate for temperature and/or manufacturing process variations.

### BRIEF SUMMARY

According to a first aspect, there is provided a data transmission circuit comprising an output branch comprising a first resistor, a first transistor, and a second transistor series-connected between a first voltage rail and a first output node, the second transistor being configured to receive on its gate a data signal; a branch of duplication of the output branch with equal dimensions, or with dimensions having a fixed ratio N, with respect to the output branch, the duplication branch comprising a second resistor, a third transistor, and a fourth transistor series-connected between the first voltage rail and a second node, the fourth transistor being configured to receive on its gate the data signal; a current source coupling the second node and a second voltage rail; and a voltage control circuit comprising an input coupled to the second node and configured to control a gate voltage of the first and third transistors based on a reference voltage.

According to an embodiment, the output branch is duplicated with a fixed ratio N, the second resistor having a resistance N times greater than the first resistance, the third transistor having a width N times smaller than a width of the first transistor, and the fourth transistor having a width N times smaller than a width of the second transistor.

According to an embodiment, the fixed ratio N is in the range from 100 to 1,000.

According to an embodiment, the circuit further comprises a fifth transistor connected between the second node and the current source.

According to an embodiment, the current source comprises a current mirror comprising a sixth transistor coupled between the second node and the second voltage rail and a seventh transistor series-connected with a variable current source between the first and second voltage rails.

According to an embodiment, the variable current source comprises a circuit for adjusting the value of the current, the adjustment circuit comprising a plurality of one-time programmable memory elements.

According to an embodiment, the voltage control circuit comprises an operational amplifier.

According to an embodiment, the control circuit is configured to control the gate voltage of the first transistor via a voltage buffer.

According to an embodiment, the first, the second, the third, and the fourth transistors are p-channel MOS-type transistors.

According to an embodiment, the first, the second, the third, and the fourth transistors are n-channel MOS-type transistors.

According to another aspect, there is provided an electronic circuit comprising a first data transmission circuit such as described hereabove and further comprising a second data transmission circuit comprising an output branch comprising a first resistor, a first transistor, and a second transistor series-connected between the second voltage rail and a first output node, the second transistor being configured to receive on its gate a data signal; a branch of duplication of the output branch with equal dimensions, or with dimensions having a fixed ratio N, with respect to the output branch, the duplication branch comprising a second resistor, a third transistor, and a fourth transistor series-connected between the second voltage rail and a second node, the fourth transistor being configured to receive on its gate the data signal; and a voltage control circuit comprising an input coupled to the second node and configured to control a gate voltage of the first and third transistors based on a reference voltage, wherein the current source of the first circuit couples the second node of the second circuit and the first voltage rail.

According to another aspect, there is provided an electronic device comprising the above-described circuit and a data processing circuit configured to generate the data signal.

According to another aspect, there is provided a method of regulating a resistance of a data transmission circuit comprising the duplication of an output branch comprising a first resistor, a first transistor, and a second transistor series-connected between a first voltage rail and a first output node, the second transistor being configured to have its gate coupled to a data signal by a branch of duplication of the first branch comprising a second resistor, a third transistor, and a fourth transistor series-connected between the voltage rail and a second node and sized identically or with a fixed ratio N with respect to the output branch, the fourth transistor being configured to have its gate coupled to the data signal; the generation of a current by a current source coupling the second node and a second voltage rail; and the control of a gate voltage of the first and third transistors based on a reference voltage by a voltage control circuit comprising an input coupled to the second node.

According to an embodiment, the second resistor, the third transistor, and the fourth transistor are sized with a fixed ratio N, the second resistor having a resistance N times greater than the first resistance, the third transistor having a width N times smaller than a width of the first transistor, and the fourth transistor having a width N times smaller than a width of the second transistor.

According to an embodiment, the fixed ratio N is in the range from 100 to 1,000.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an example of an electronic data transmission circuit according to an embodiment of the present disclosure;

FIG. 2 shows another example of an electronic data transmission circuit according to another embodiment of the present disclosure;

FIG. 3 schematically shows in the form of blocks a complementary data transmission circuit comprising the electronic circuits of FIGS. 1 and 2;

FIG. 4 shows an example of a circuit of a variable current source of FIGS. 1 to 3;

FIG. 5 is a graph showing an example of the density of probability of the output resistances of the device of FIG. 3;

FIG. 6 shows in the form of blocks an example of a communication circuit comprising the circuit of FIG. 1, 2, or 3; and

FIG. 7 shows in the form of blocks an example of a communication device comprising the circuit of FIG. 1, 2, 3, or 6.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, one-time programmable memories are known to those skilled in the art and have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements, such as one or more resistors or one or more voltage buffers.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

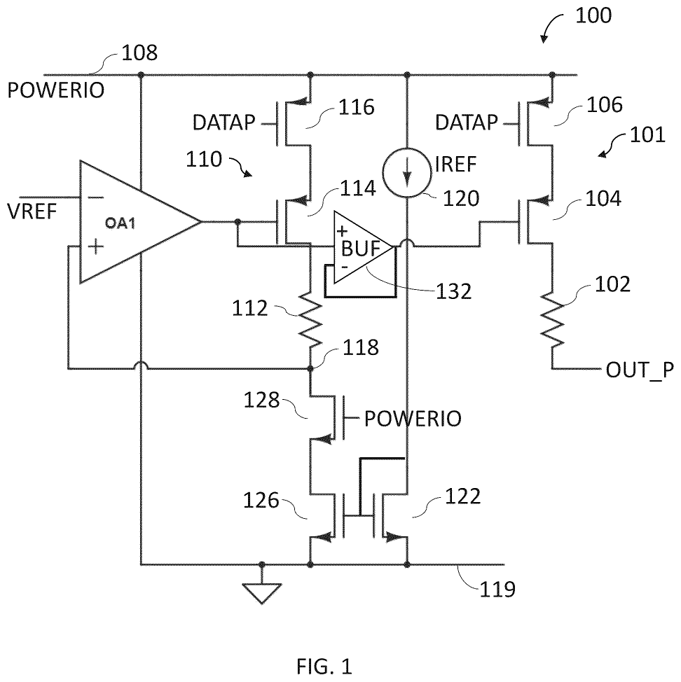

FIG. 1 shows an example of a data transmission electronic circuit 100 according to an embodiment of the present disclosure.

Electronic circuit 100 comprises an output branch 101 comprising a first resistor 102, a first transistor 104, and a second transistor 106 series-connected between an output node OUT_P and a voltage rail 108 having a voltage POWERIO for example applied thereto. The equivalent resistance ROUT at the output of circuit 100 is equal to the sum of the value of the first resistance 102, of the equivalent resistance of the first transistor 104, and of the equivalent resistance of the second transistor 106. Transistors 104 and 106 are, in the example of FIG. 1, p-channel MOS-type transistors, although other types of transistors may be used.

In the example of FIG. 1, the source of transistor 106 is connected to voltage rail 108 and the drain of transistor 106 is connected to the source of transistor 104. The drain of transistor 104 is connected to a first node of resistor 102 and a second node of resistor 102 is connected to output node OUT_P. According to embodiments, the order of elements 102, 104, and 106 could be different from that of the example of FIG. 1.

Transistor 106 is configured to receive on its gate a data signal DATAP to be transmitted via output node OUT_P.

Circuit 100 also comprises a branch 110 of duplication of output branch 101 comprising a second resistor 112, a third transistor 114, and a fourth transistor 116 series-connected between voltage rail 108 and a node 118.

Transistors 114 and 116 are, for example, transistors of the same type as transistors 104 and 106.

In the example of FIG. 1, the source of transistor 116 is connected to voltage rail 108 and the drain of transistor 116 is connected to the source of transistor 114. The drain of transistor 114 is connected to a first node of resistor 112 and a second node of resistor 112 is connected to node 118. According to embodiments, the order of elements 112, 114, and 116 may be different from that of the example of FIG. 1.

Transistor 116 is configured to receive on its gate data signal DATAP.

According to an embodiment, branches 101 and 110 have equal dimensions. In this case, resistance 112 has a value equal to the value of resistance 102, transistor 114 has a width equal to the width of transistor 104, and transistor 116 has a width equal to the width of transistor 106, so that the equivalent resistance of these three components in series is identical to within 5% to ROUT.

According to another embodiment, branch 110 is of dimensions with a fixed ratio N with respect to branch 101. In this case, resistance 112 is N times larger than resistance 102, transistor 114 has a width N times smaller than the width of transistor 104, and transistor 116 has a width N times smaller than the width of transistor 106. For example, the fixed ratio N is in the range from 100 to 1,000 so that the equivalent resistance of components 112, 114, and 116 in series is identical, to within 5%, to ROUT multiplied by the fixed ratio N. An advantage of using components with higher equivalent resistances is that a lower current flows through these components for same voltage values. This facilitates an adjustment of the equivalent resistance of the components.

Components 112, 114, and 116 are positioned so that they undergo temperature variations similar to components 102, 104, and 106, and to copy the corresponding variations of ROUT.

Node 118 is coupled to a second voltage rail 119, for example a ground rail, via a current source 126. Current source 126 is for example formed by a transistor 126, a current mirror comprising transistor 126, and a variable current source 120. Transistor 126 forms a branch of the current mirror, the second branch of the current mirror being for example implemented by a transistor 122 coupled in series with variable current source 120 between voltage rails 108 and 119. In the example of FIG. 1, the drain of transistor 126 is coupled to node 118, the source of transistor 126 is coupled to voltage rail 119, and the gate of transistor 126 is connected to the gate and to the drain of transistor 122. The source of transistor 122 is coupled to voltage rail 119 and the drain of transistor 122 is coupled to the gates of transistors 122 and 126 and to variable current source 120. For example, the presence of the current mirror enables to better power variable current source 120 and to have a better mirror between current IREF and the current on the branch of the current mirror formed by transistor 126. According to an embodiment, the current mirror formed by transistors 122 and 126 is omitted and variable current source 120 is directly coupled to node 118.

Variable current source 120 is configured to generate a current IREF. The value of current IREF is for example adjusted to compensate for variations due to a variability in the manufacturing processes involved during the manufacturing of electronic circuit 100.

According to an embodiment, a transistor 128 is connected between current source 126 and node 118. The gate of transistor 128 is connected to voltage rail 108. Transistor 128 is configured to be cascode-connected to current source 126. In embodiments comprising the current mirror, transistor 128 is configured to ensure that the voltage difference between the drain and the source of transistor 126 is similar to the voltage difference between the drain and the source of transistor 122, which enables the output current of the drain of transistor 126 to be similar to IREF. According to other embodiments, transistor 128 is not present in circuit 100 and the drain of transistor 126 or variable current source 120 is directly connected to node 118.

In the example of FIG. 1, transistors 122, 126, and 128 are n-channel MOS transistors, although other transistor types can be used.

Electronic circuit 100 also comprises a voltage control circuit OA1. Circuit OA1 comprises an input coupled to node 118 and an output coupled to the gate of transistor 114 and coupled to the gate of transistor 104. For example, circuit OA1 is formed by an operational amplifier configured so that its positive input is coupled to node 118, its negative input is powered with a voltage VREF, and its output is coupled to the gate of transistor 114. Control circuit OA1 is configured to adjust the voltage on the gate of transistor 114 so that the voltage at node 118 is equal to voltage VREF. Thus, when the current flowing through resistor 112 and transistors 114 and 116 varies, for example as a response to a temperature variation, the voltage at node 118 also varies, and this variation is corrected by control circuit OA1. The variations undergone by duplication branch 110 being similar to the variations undergone by output branch 101, the same voltage correction applied to the gate of transistor 104 also corrects the current variations flowing through resistor 102 and transistors 104 and 106.

According to an embodiment, circuit 100 for example further comprises a voltage buffer 132 (“BUF”). In the example of FIG. 1, control circuit OA1 is configured to control the gate voltage of the first transistor 104 via a voltage buffer 132. Voltage buffer 132 is for example formed by an even number of inverters coupled in series or, as shown in FIG. 1, by a follower-assembled operational amplifier. Operational amplifier 132 is configured to receive the output signal of control circuit OA1 on its positive input and so that its output is connected to its negative input. The output of voltage buffer 132 is also coupled to the gate of transistor 104.

Voltage buffer 132 is configured to isolate branches 101 and 110 and, for example, avoid for current intensity variations on the gate of transistor 104, for example due to the transmission of data signal DATAP, to have an effect on the gate of transistor 114.

Circuit 100 for example comprises additional components, not shown in FIG. 1.

Although not illustrated in the example of FIG. 1, circuit 100 for example comprises other circuits and/or electronic components connected between node OUT_P and a data transmission terminal.

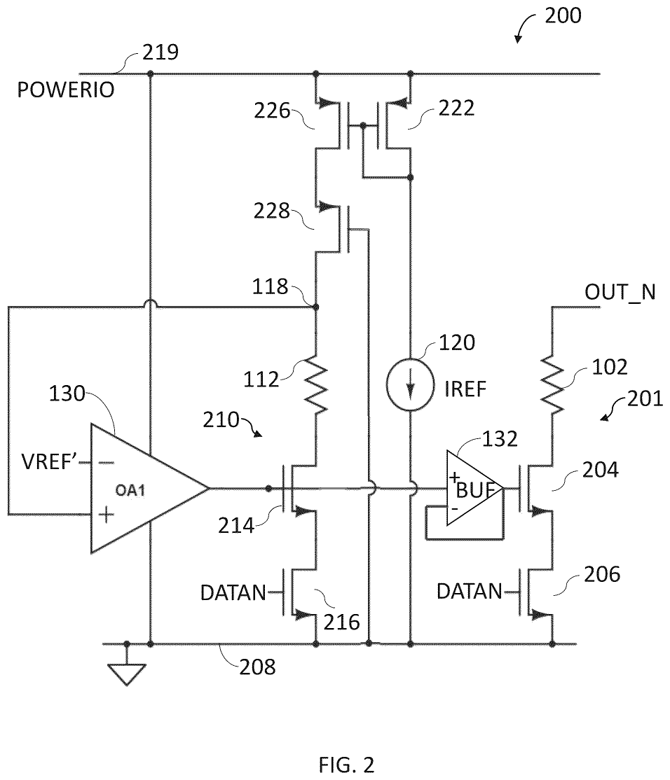

FIG. 2 shows another example of an electronic data transmission circuit 200 according to another embodiment of the present disclosure.

Certain elements of FIG. 2 are identical to elements of FIG. 1. They are shown with the same reference and will not be detailed again.

The circuit 200 of FIG. 2 corresponds to the circuit 100 of FIG. 1, in which:
voltage rail 108 becomes a voltage rail 208 configured to be a ground rail and voltage rail 119 becomes a voltage rail 219 configured to be powered with voltage POWERIO;
output branch 101 becomes an output branch 201 and duplication branch 110 becomes a duplication branch 210;
p-channel MOS-type transistors 104, 106, 114, and 116 become n-channel MOS-type transistors 204, 206, 214, and 216, and n-channel channel MOS-type transistors 122, 126, and 128 become p-channel MOS-type transistors 222, 226, and 228;
the data signal DATAP to be transmitted via output node OUT_P by circuit 100 becomes a data signal DATAN to be transmitted via an output node OUT_N by circuit 200;
control circuit 130 uses a reference voltage VREF′, for example the dual of the voltage VREF used for circuit 100, that is, the same voltage as reference voltage VREF but referenced to voltage POWERIO. For example, VREF′=POWERIO−VREF;
variable current source 120 is coupled to voltage rail 208 and is series-connected with transistor 222.

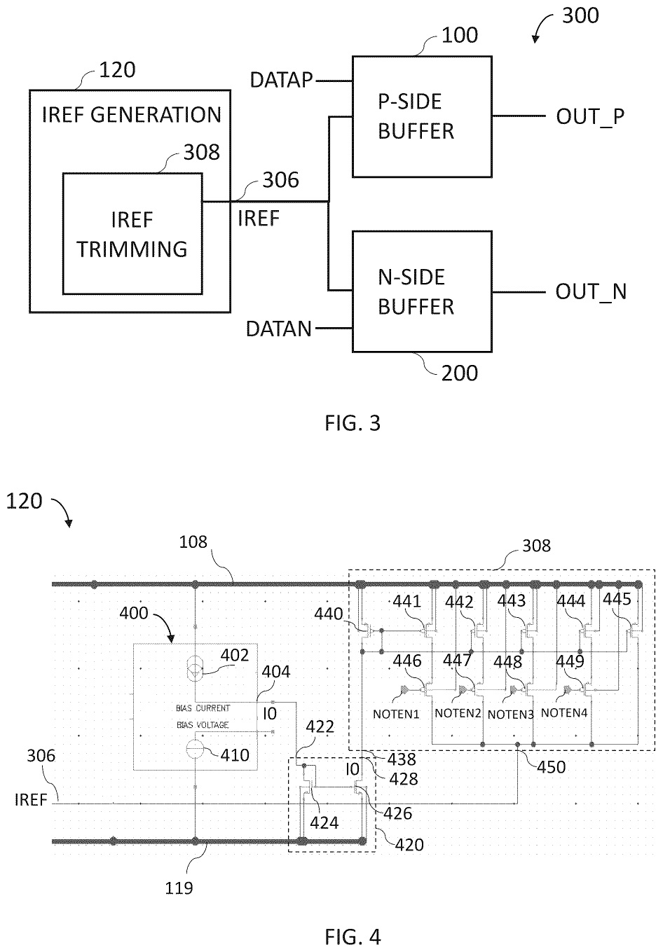

FIG. 3 schematically shows in the form of blocks an electronic circuit 300 for transmitting complementary data signals, comprising the electronic circuits 100, 200 of FIGS. 1 and 2.

The variable current sources 120 shown in circuit 100 in FIG. 1 and in circuit 200 in FIG. 2 are, for example, formed by a single circuit 120 (“IREF GENERATION”) of FIG. 3 configured to generate reference current IREF at an output 306 coupled to the two circuits 100, 200.

Circuit 120 for example comprises a circuit 308 (“IREF TRIMMING”) configured to adjust the value of current IREF.

Circuit 100 (“P-SIDE BUFFER”) is configured to receive data signal DATAP at an input and to deliver an output signal via node OUT_P, and circuit 200 (“N-SIDE BUFFER”) is configured to receive data signal DATAN at an input and to deliver an output signal via node OUT_N.

FIG. 4 shows an example of a circuit of the variable current source 120 of FIGS. 1 to 3.

Variable current source 120 comprises, for example, a circuit 400 comprising, for example, a current generator 402 for example coupled to voltage rail 108 and configured to generate a current IO (“BIAS CURRENT”) at an output 404. Current I0 is for example in the range from 1 nA to 1 mA and for example from 1 μA to 20 μA and for example in the order of 10 μA.

Circuit 400 for example comprises other electronic components, for example a voltage generator 410 configured to generate a bias voltage (“BIAS VOLTAGE”).

Variable current source 120 for example further comprises a circuit 420 coupled to circuit 400 and configured to receive current I0 on an input 422. Circuit 420 comprises, for example, two transistors 424 and 426 configured to form a current mirror. Circuit 420 is configured, for example, to replicate current I0 on an output 428. According to another embodiment, circuit 420 is configured to transmit to output 428 a current with a value proportional to current I0 . The substrate of transistors 424 and 426 is, for example, coupled to voltage rail 119.

Variable current source 120 further comprises circuit 308. Circuit 308 comprises, for example, an input 438 coupled to the output 428 of circuit 420 and configured to receive current I0. Circuit 308 comprises, for example, 5 transistors, for example of p-channel MOS type, for example a transistor 440 and transistors 441 to 445. Transistors 441 to 445 are each configured to form a current mirror with transistor 440. Each of the sources of transistors 440 to 445 is coupled to voltage rail 108, and each of the gates of transistors 441 to 445 is coupled to the gate and to the drain of transistor 440, which are coupled to input 438. Circuit 308 further comprises, for example, 4 transistors 446 to 449 configured to enable or disable the branches of the current mirror comprising transistors 441 to 444 respectively. Each of the sources of transistors 446 to 449 is coupled to the drain of transistors 441 to 444 respectively and enable signals “NOTEN1, . . . , NOTEN4” are received on each of the gates of transistors 446 to 449 respectively. The enable signals enable to independently enable one or a multitude of branches of the current mirror formed of transistor 440 and of transistors 441 to 445 to modify the value of the current IREF flowing at an output 450 of circuit 308 and coupled to the output 306 of variable current source 120.

According to an embodiment, each of the enable signals received on each of the gates of transistors 446 to 449 is irreversibly programmed during a calibration (trimming) phase, for example by a one-time programmable memory cell.

For example, if the signal NOTEN1 at the gate of transistor 446 is at the value of voltage rail 108, transistor 446 is off and this branch of the current mirror formed of transistors 440 and 441 is disabled. Conversely, if signal NOTEN1 is at the value of voltage rail 119, transistor 446 is on and this branch of the current mirror formed of transistors 440 and 441 is enabled. The drains of transistors 446 to 449 and the drain of transistor 445 are coupled to output 450, where the currents originating from the 5 branches of the current mirror add. The current originating from each of the current mirror branches depends on the sizing of transistors 441 to 445, and in particular on the width of their gate, with respect to the size of transistor 440. The substrate of transistors 440 to 449 is for example coupled to voltage rail 108.

According to an embodiment, transistors 440 to 445 have the same sizing and the value of IREF may take values I0, 2×I0, 3×I0, 4×I0, and 5×I0 according to the number of enabled branches of the current mirror.

According to another embodiment, transistor 445 has the same sizing as transistor 440, the gate width of transistor 444 is half the gate width of transistor 440, the gate width of transistor 443 is four times smaller than the gate width of transistor 440, and the gate width of transistor 442 is eight times smaller than the gate width of transistor 440. The gate width of transistor 441 is sized, for example, to optionally add an offset to current value IREF. This sizing allows a greater number of possible values for IREF, for example equal to two to the power of three, and a greater accuracy of the value of current IREF, the accuracy being given by the branch of the current mirror formed by transistor 442.

Although a current mirror with 5 branches is illustrated in the circuit 308 of FIG. 4, it will be obvious to those skilled in the art that a current mirror with a different number of branches may be implemented.

Although, in the example shown in FIG. 4, the transistors 440 to 449 of circuit 308 are p-channel MOS transistors, other transistor types may be used.

Circuit 308 enables to vary the value of the reference current IREF used by circuits 100 and 200. This circuit is for example used to compensate for possible variations in the parameters and quantities of circuits 100, 120, and 200 due to manufacturing process variations.

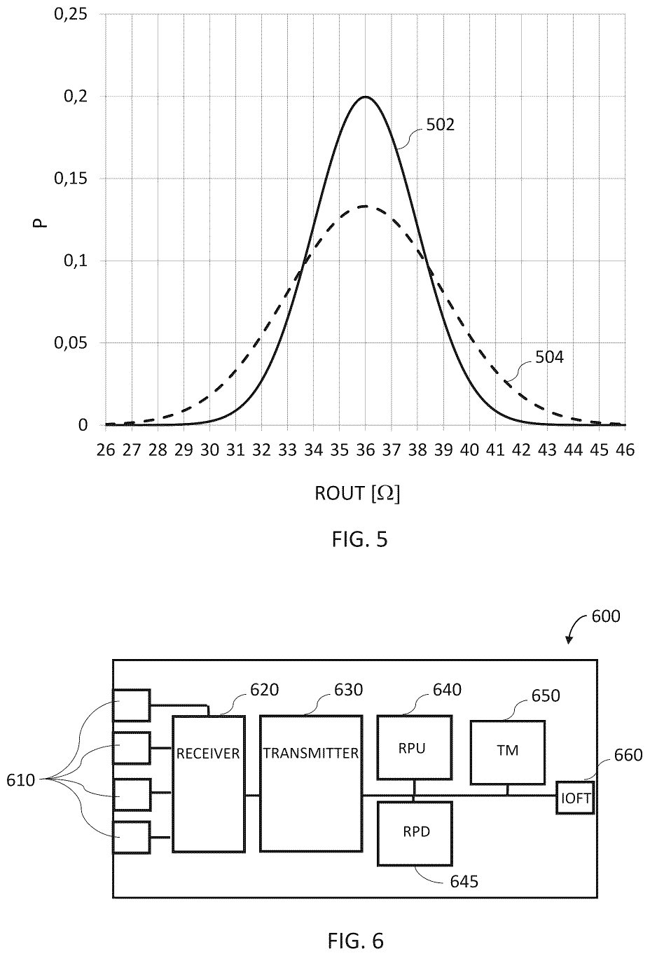

FIG. 5 is a graph showing an example of the density of probability (“P”) of the output resistances (“ROUT”) of the device of FIG. 3 and, in particular, the resistance of the components 102, 104, and 106 of the circuit 100 of FIG. 1 and the resistance of the components 102, 204, and 206 of the circuit 200 of FIG. 2.

For example, a standard may impose a range of authorized values for an output resistance of a circuit. For example, for the USB LSFS (Universal Serial Bus Low Speed Fast Speed) standard, output resistance ROUT is defined as being in the range from 28 to 44 Ohms.

Curve 502 shows the distribution of the output resistances ROUT of the device 300 of FIG. 3. For example, device 300 has a 20% chance of having an output resistance equal to 36 Ohms.

Curve 504 shows an example of the distribution of the output resistances of a sub-optimal circuit, not shown, which does not comprise the duplication branch 101, 201, the control circuit OA1, and the current source 120, 122, 126, 222, 226 of FIGS. 1 and 2.

The probability for the output resistance of device 300 to be equal to 36 Ohms is greater than that of the device of curve 504. Further, the probability for the output resistance of device 300 to be lower than 33.5 Ohms and to be greater than 38.5 Ohms is lower than that of the device of curve 504. Device 300 exhibits less variability in the output resistance distribution.

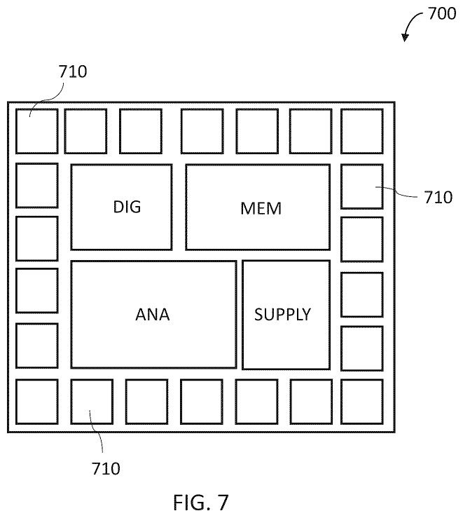

FIG. 6 shows in the form of blocks an example of a communication circuit 600 comprising the circuit 100, 200, or 300 of FIG. 1, 2, or 3 respectively.

Communication circuit 600 comprises, for example, a set of input connection terminals 610 configured to receive signals from an electronic circuit, not shown in FIG. 6, and to transmit the signals to a receiver circuit 620 (“RECEIVER”). Receiver circuit 620 comprises, for example, inputs coupled to connection terminals 610 and is for example configured to receive the signals and to transmit them to a transmitter 630 (“TRANSMITTER”). Transmitter 630 is configured to transmit a signal to an output terminal 660 (“IOFT”, Input/Output Five Volt Tolerant) and comprises, for example, the circuit 100, 200, or 300 of FIG. 1, 2, or 3 respectively, to ensure that the output resistance of transmitter 630 and of communication circuit 600 at terminal 660 is temperature-stable and stable with respect to manufacturing process variations. Communication circuit 600 also comprises a pull-up resistor 640 (RPU) and a pull-down resistor 645 (RPD) connected to an output of transmitter 630. A test circuit 650 (TM for “Test Mode”) is for example coupled to the output of transmitter 630 to test communication circuit 600 for example during its development.

FIG. 7 shows in the form of blocks an example of a communication device 700 comprising the circuit 100, 200, 300, or 600 of FIG. 1, 2, 3, or 6 respectively.

Device 700 comprises, for example, a set of circuits including a memory (“MEM”), an analog circuit (“ANA”), a digital circuit (“DIG”), and a power supply circuit (“SUPPLY”).

Device 700 comprises, for example, a set of input and output connection terminals 710 configured to transmit and/or to receive signals (only part of which is referenced to avoid cluttering the drawing). One or a plurality of connection terminals 710 comprise, for example, the circuit 100, 200, 300, or 600 of FIG. 1, 2, 3, or 6 respectively.

Device 700 is, for example, an electronic chip embedded in a laptop computer, an electronic tablet, a cell phone, a USB stick, or a similar device.

Various embodiments and variants have been described. Those skilled in the art will understand that certain features of these various embodiments and variants may be combined, and other variants will occur to those skilled in the art. In particular, although the examples have been described with MOS transistors, in other examples of embodiments, the use of bipolar transistors may be envisaged.

Finally, the practical implementation of the described embodiments and variants is within the abilities of those skilled in the art based on the functional indications given hereabove.

1. A data transmission circuit comprising:
an output branch comprising a first resistor, a first transistor, and a second transistor series-connected between a first voltage rail and a first output node, the second transistor being configured to receive on its gate a data signal;
a branch of duplication of the output branch with equal dimensions, or with dimensions having a fixed ratio N, with respect to the output branch, the duplication branch comprising a second resistor, a third transistor, and a fourth transistor series-connected between the first voltage rail and a second node, the fourth transistor being configured to receive on its gate the data signal;
a current source coupling the second node and a second voltage rail, the current source generating a current; and
a voltage control circuit comprising an input coupled to the second node and configured to control a gate voltage of the first and third transistors based on a reference voltage.

2. The circuit according to claim 1, wherein the output branch is duplicated with a fixed ratio N, the second resistor having a resistance I N times greater than the first resistance, the third transistor having a width N times smaller than a width of the first transistor, and the fourth transistor having a width N times smaller than a width of the second transistor.

3. The circuit according to claim 2, wherein the fixed ratio N is in a range from 100 to 1,000.

4. The circuit according to claim 1, further comprising a fifth transistor connected between the second node and the current source.

5. The circuit according to claim 1, wherein the current source comprises a current mirror comprising a sixth transistor coupled between the second node and the second voltage rail and a seventh transistor series-connected with a variable current source between the first and second voltage rails.

6. The circuit according to claim 5, wherein the variable current source comprises a circuit for adjusting a value of the current, the adjustment circuit comprising a plurality of one-time programmable memory elements.

7. The circuit according to claim 1, wherein the voltage control circuit comprises an operational amplifier.

8. The circuit according to claim 1, wherein the control circuit is configured to control the gate voltage of the first transistor via a voltage buffer.

9. The circuit according to claim 1, wherein the first, the second, the third, and the fourth transistors are p-channel MOS-type transistors.

10. The c according to claim 1, wherein the first, the second, the third, and the fourth transistors are n-channel MOS-type transistors.

11. An electronic circuit comprising:
a first data transmission circuit comprising:
an output branch comprising a first resistor, a first transistor, and a second transistor series-connected between a first voltage rail and a first output node, the second transistor being configured to receive on its gate a data signal;
a branch of duplication of the output branch with equal dimensions, or with dimensions having a fixed ratio N, with respect to the output branch, the duplication branch comprising a second resistor, a third transistor, and a fourth transistor series-connected between the first voltage rail and a second node, the fourth transistor being configured to receive on its gate the data signal;
a current source coupling the second node and a second voltage rail; and
a voltage control circuit comprising an input coupled to the second node and configured to control a gate voltage of the first and third transistors based on a reference voltage; and
a second data transmission circuit comprising:
an output branch comprising a first resistor, a first transistor, and a second transistor series-connected between the second voltage rail and a first output node, the second transistor being configured to receive on its gate a data signal;
a branch of duplication of the output branch with equal dimensions, or with dimensions having a fixed ratio N, with respect to the output branch, the duplication branch comprising a second resistor, a third transistor, and a fourth transistor series-connected between the second voltage rail and a second node, the fourth transistor being configured to receive on its gate the data signal; and
a voltage control circuit comprising an input coupled to the second node and configured to control a gate voltage of the first and third transistors based on a reference voltage,
wherein the current source of the first circuit couples the second node of the second circuit and the first voltage rail.

12. A method of regulating a resistance of a data transmission circuit, the method comprising:
duplicating an output branch comprising a first resistor, a first transistor, and a second transistor series-connected between a first voltage rail and a first output node, the second transistor being configured to have its gate coupled to a data signal by a branch of duplication of the output branch comprising a second resistor, a third transistor, and a fourth transistor series-connected between the voltage rail and a second node and sized identically or with a fixed ratio N with respect to the output branch, the fourth transistor being configured to have its gate coupled to the data signal;
generating a current by a current source coupling the second node and a second voltage rail; and
controlling a gate voltage of the first and third transistors based on a reference voltage by a voltage control circuit comprising an input coupled to the second node.

13. The method according to claim 12, wherein the second resistor, the third transistor, and the fourth transistor are sized with a fixed ratio N, the second resistor having a resistance N times greater than the first resistance, the third transistor having a width N times smaller than a width of the first transistor, and the fourth transistor having a width N times smaller than a width of the second transistor.

14. The method according to claim 13, wherein the fixed ratio N is in a range from 100 to 1,000.
